(19) United States
(12) Patent Application Publication
(10) Pub. No.: US 2020/0235142 A1
(43) Pub. Date: Jul. 23, 2020

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventors: Hiromasa SAITO, Kanagawa (JP); Shohei SHIMADA, Kanagawa (JP)

(73) Assignee: SONY SEMICONDUCTOR SOLUTIONS CORPORATION, Kanagawa (JP)

(21) Appl. No.: 16/634,313

(22) PCT Filed: May 22, 2018
(86) PCT No.: PCT/JP2018/019617

§ 371 Date: Jan. 27, 2020

(30) Foreign Application Priority Data
Aug. 3, 2017 (JP) 2017-150506

(51) Int. Cl. H01L 27/146; H04N 5/369

(52) U.S. Cl. CPC H01L 27/1463; H01L 27/14625; H04N 5/3696

(57) ABSTRACT

Provided are a solid-state imaging device and an electronic device in which the influence of dark current is reduced. The solid-state imaging device includes a plurality of first pixel units arranged in a matrix, each first pixel unit having one pixel and one on-chip lens, at least one second pixel unit having two pixels and one on-chip lens provided across the two pixels, a pixel separation layer, and at least one contact that exists within a region of the second pixel unit or is provided under the pixel separation layer adjacent to the region of the second pixel unit, and connects the pixel separation layer to a reference potential wiring, in which the second pixel units are arranged at predetermined intervals at least in a row extending in a first direction of the matrix of the first pixel units.

### FIELD

The present disclosure relates to a solid-state imaging device and an electronic device.

### BACKGROUND

In recent years, there has been a demand for further downsizing and higher image quality in solid-state imaging devices. The solid-state imaging device is configured, for example, by arranging photoelectric conversion elements such as photodiodes in a matrix on a planar semiconductor substrate.

Here, each photoelectric conversion element is configured by combining a p-type semiconductor and an n-type semiconductor, and the photoelectric conversion elements are separated from each other in a pixel by a pixel separation layer fixed to a reference potential. However, in such a solid-state imaging device, a dark signal may increase due to an increase in dark current in the vicinity of a contact which connects the pixel separation layer to a reference potential line (e.g., a ground line).

For example, Patent Literature 1 below discloses a solid-state imaging device including an effective pixel portion where light from an imaging target enters and a light-shielding pixel portion where light is shielded, and a signal of the light-shielding pixel portion is subtracted from the signal of the effective pixel portion to acquire a signal from which the influence of dark current is removed.

### CITATION LIST

### Patent Literature

Patent Literature 1: JP 2008-236787 A

### SUMMARY

### Technical Problem

However, the solid-state imaging device disclosed in Patent Literature 1 described above does not reduce the absolute magnitude of the generated dark current. In addition, the solid-state imaging device disclosed in Patent Literature 1 generates a difference in the magnitude of the dark current between a pixel adjacent to the contact that fixes the pixel separation layer to the reference potential and a pixel not adjacent to the contact, causing streak-like image quality degradation to be found in the dark.

Therefore, there has been a demand for a technique capable of reducing the magnitude of dark current and an inter-pixel difference due to the contact that fixes the pixel separation layer to the reference potential in the solid-state imaging device.

### Solution to Problem

According to the present disclosure, a solid-state imaging device is provided that includes: a plurality of first pixel units arranged in a matrix, each first pixel unit having one pixel and one on-chip lens provided on the one pixel; at least one second pixel unit having two pixels and one on-chip lens provided across the two pixels and arranged within a matrix of the first pixel units; a pixel separation layer that separates a photoelectric conversion layer included in each pixel of the first pixel unit from a photoelectric conversion layer included in the second pixel unit; and at least one contact that exists within a region of the second pixel unit or is provided under the pixel separation layer adjacent to the region of the second pixel unit, and connects the pixel separation layer to a reference potential wiring, wherein the second pixel units are arranged at predetermined intervals at least in a row extending in a first direction of the matrix of the first pixel units.

Moreover, according to the present disclosure, an electronic device is provided that includes a solid-state imaging device that electronically captures an imaging target, the solid-state imaging device including a plurality of first pixel units arranged in a matrix, each first pixel unit having one pixel and one on-chip lens provided on the one pixel, at least one second pixel unit having two pixels and one on-chip lens provided across the two pixels and arranged within a matrix of the first pixel units, a pixel separation layer that separates a photoelectric conversion layer included in each pixel of the first pixel unit from a photoelectric conversion layer included in the second pixel unit, and at least one contact that exists within a region of the second pixel unit or is provided under the pixel separation layer adjacent to the region of the second pixel unit, and connects the pixel separation layer to a reference potential wiring, wherein the second pixel units are arranged at predetermined intervals at least in a row extending in a first direction of the matrix of the first pixel units.

According to the present disclosure, the contacts that fix the pixel separation layers separating the photoelectric conversion elements to the reference potential can be arranged at an appropriate density. In addition, it is possible to reduce the influence of the dark current increasing around the contact on the image quality of the captured image.

### Advantageous Effects of Invention

As described above, according to the present disclosure, it is possible to provide a solid-state imaging device and an electronic device in which the magnitude of the dark current and the inter-pixel difference due to the contact that fixes the pixel separation layer to the reference potential are reduced.

Note that the above effects are not necessarily limited, and any of the effects illustrated in the present specification, or other effects that can be grasped from the present specification, together with or in place of the above effects.

### BRIEF DESCRIPTION OF DRAWINGS

FIG. 1 is an explanatory diagram schematically illustrating an outline of an imaging device using a solid-state imaging device.

FIG. 2A is an explanatory diagram schematically illustrating an example of the positional relationship between pixels included in a pixel region and a contact that fixes a pixel separation layer defining each pixel to a reference potential.

FIG. 2B is an explanatory diagram schematically illustrating another example of the positional relationship between pixels included in the pixel region and the contact that fixes the pixel separation layer defining each pixel to the reference potential.

FIG. 3 is a schematic explanatory diagram illustrating a planar configuration of a pixel region included in a solid-state imaging device according to an embodiment of the present disclosure.

FIG. 4 is a schematic plan view for explaining the arrangement of reference potential lines for unit pixels in the pixel region.

FIG. 5 is a schematic plan view for explaining the arrangement of second pixel units in a range of the pixel region wider than that of FIG. 3.

FIG. 6A is a schematic cross-sectional view of the pixel region illustrated in FIG. 3 cut along a plane A-AA.

FIG. 6B is a schematic cross-sectional view of the pixel region illustrated in FIG. 3 cut along a plane B-BB.

FIG. 7 is a schematic explanatory diagram illustrating an example of a planar configuration of a pixel region included in a solid-state imaging device according to a first modification.

FIG. 8 is a schematic plan view illustrating the arrangement of second pixel units in a range of the pixel region wider than that of FIG. 7.

FIG. 9 is a schematic explanatory diagram illustrating another example of the planar configuration of the pixel region included in the solid-state imaging device according to the first modification.

FIG. 10 is a schematic plan view illustrating the arrangement of second pixel units in a range of the pixel region wider than that in FIG. 9.

FIG. 11A is an explanatory view illustrating, in an enlarged manner, the vicinity of a pixel region where a second pixel unit is provided to illustrate a variation in position of the contact.

FIG. 11B is an explanatory view illustrating, in an enlarged manner, the vicinity of the pixel region where the second pixel unit is provided to illustrate a variation in position of the contact.

FIG. 11C is an explanatory diagram illustrating, in an enlarged manner, the vicinity of the pixel region where the second pixel unit is provided to illustrate a variation in position of the contact.

FIG. 12 is a schematic cross-sectional view illustrating a variation in position of the contact in the cross-sectional structure obtained by cutting the pixel region illustrated in FIG. 3 along the plane A-AA.

FIG. 13A is a schematic cross-sectional view of the pixel region illustrated in FIG. 3 cut along the plane A-AA in a third modification.

FIG. 13B is a schematic cross-sectional view of the pixel region illustrated in FIG. 3 cut along the plane B-BB in the third modification.

FIG. 14A is a schematic cross-sectional view for explaining a manufacturing step of a method for manufacturing the solid-state imaging device according to the present embodiment.

FIG. 14B is a schematic cross-sectional view illustrating a manufacturing step in the method for manufacturing the solid-state imaging device according to the present embodiment.

FIG. 14C is a schematic cross-sectional view for explaining a manufacturing step of the method for manufacturing the solid-state imaging device according to the present embodiment.

FIG. 14D is a schematic cross-sectional view for explaining a manufacturing step of the method for manufacturing the solid-state imaging device according to the present embodiment.

FIG. 15A is an external view illustrating an example of an electronic device to which the solid-state imaging device according to the present embodiment can be applied.

FIG. 15B is an external view illustrating another example of an electronic device to which the solid-state imaging device according to the present embodiment can be applied.

FIG. 15C is an external view illustrating another example of an electronic device to which the solid-state imaging device according to the present embodiment can be applied.

FIG. 16A is a block diagram illustrating an example of a schematic configuration of a vehicle control system.

FIG. 16B is an explanatory diagram illustrating an example of installation positions of a vehicle exterior information detection unit and an imaging unit.

### DESCRIPTION OF EMBODIMENTS

Hereinafter, preferred embodiments of the present disclosure will be described in detail with reference to the accompanying drawings. Note that, in the present specification and the drawings, the same reference numerals are assigned to the constituent components having substantially the same functional configuration and the description thereof will not be repeated.

Note that the description will be made in the following order.

0. Technical Background of the Present Disclosure

1. Configuration
1.1 Planar Configuration
1.2 Cross-Sectional Configuration

2. Modification
2.1 First Modification
2.2 Second Modification
2.3 Third Modification

3. Manufacturing Method

4. Application Examples
4.1 First Application Example
4.2 Second Application Example

### 0. Technical Background of the Disclosure

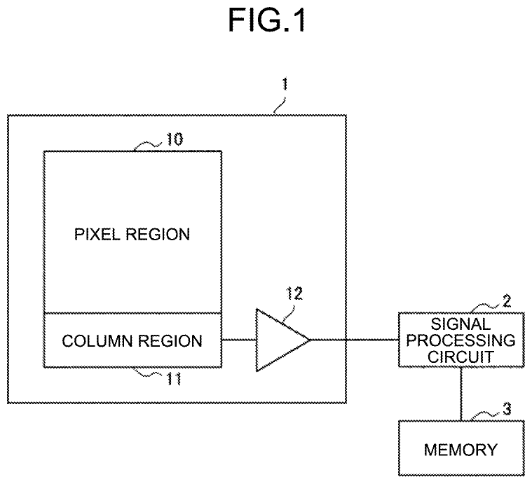

First, a schematic configuration of an imaging device to which the technique according to the present disclosure is applied is described with reference to FIG. 1. FIG. 1 is an explanatory diagram schematically illustrating an outline of an imaging device using a solid-state imaging device.

As illustrated in FIG. 1, the imaging device includes a solid-state imaging device 1, a signal processing circuit 2, and a memory 3.

The solid-state imaging device 1 includes a pixel region 10, a column region 11, and an output amplifier 12, and generates an image signal of an imaging target by converting light emitted from the imaging target into an electrical signal. Specifically, the pixel region 10 is configured by arranging pixels including photoelectric conversion elements in a two-dimensional matrix, and converts light incident on each pixel into a signal charge by the photoelectric conversion elements. The column region 11 is formed of a transistor or the like, and reads out the signal charges generated in the pixels of the pixel region 10 for each column (i.e., pixel column) and performs signal processing such as noise removal, amplification, and analog to digital (A/D) conversion. The output amplifier 12 is formed of a transistor or the like, and amplifies the image signal output from the column region 11 and outputs the image signal to the signal processing circuit 2 provided outside the solid-state imaging device 1.

The signal processing circuit 2 is, for example, an arithmetic processing circuit that performs various corrections and the like on the image signal output from the solid-state imaging device 1. The memory 3 is, for example, a volatile or non-volatile storage device that stores the image signal, to which various corrections and the like are performed by the signal processing circuit 2, in units of frames.

With this configuration, the imaging device, first, converts light incident on each pixel in the pixel region 10 into a charge signal by the photoelectric conversion element. Subsequently, the charge signal (analog signal) read from each pixel in the pixel region 10 is amplified in the column region 11, and the charge signal is converted into a digital signal by A/D conversion. The converted digital signal is output to the external signal processing circuit 2 via the output amplifier 12.

In such a solid-state imaging device 1, a dark current generated in each pixel may cause an increase in noise of the image signal and a fixed pattern noise due to a difference in the magnitude of the dark current between pixels.

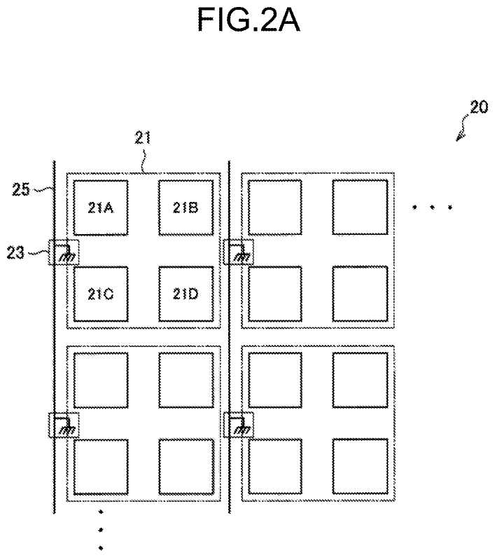

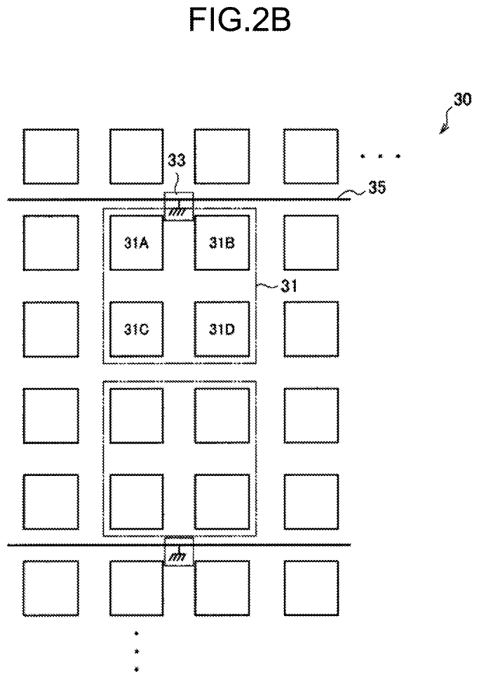

Here, the generation of the dark current in the pixel region 10 is described with reference to FIGS. 2A and 2B. FIG. 2A is an explanatory diagram schematically illustrating an example of the positional relationship between pixels included in the pixel region and a contact that fixes a pixel separation layer defining each pixel to a reference potential, and FIG. 2B is an explanatory diagram schematically illustrating another example of the positional relationship between pixels included in the pixel region and the contact that fixes the pixel separation layer defining each pixel to the reference potential.

With the arrangement illustrated in FIG. 2A, the solid-state imaging device includes in a pixel region 20 in which one pixel 21 is formed by a plurality of sub-pixels 21A, 21B, 21C, and 21D. The sub-pixels 21A, 21B, 21C, and 21D are separated from each other by a pixel separation layer (a region other than the pixels in FIG. 2A).

Note that, hereinafter, each of the sub-pixels constituting the pixel 21 is referred to as a unit pixel to distinguish it from the pixel 21 formed of the sub-pixels 21A, 21B, 21C, and 21D.

For example, the sub-pixels 21A, 21B, 21C, and 21D may be provided as a pixel (red pixel) with a red color filter (CF), a pixel (green pixel) with a green CF, a pixel (green pixel) with a blue CF, and a pixel (white pixel) with no CF, respectively. At the sub-pixels 21A, 21B, 21C, and 21D, the light passes through the CFs corresponding to individual colors, enters a photodiode (PD) provided inside the pixel, and is photoelectrically converted to obtain signal charges corresponding to the individual colors.

Here, the pixel separation layer that separates the unit pixels such as the sub-pixels 21A, 21B, 21C, and 21D from each other is connected to a reference potential line 25 (e.g., a ground line) by a contact 23 which is provided for each pixel 21. For example, in the arrangement illustrated in FIG. 2A, the contact 23 connected to the potential line 25 is provided on the left side of each pixel 21 (when FIG. 2A is viewed from the front). With this configuration, the pixel separation layer is fixed to the reference potential, so that shading, for example, of a signal output from each unit pixel can be prevented.

However, in the unit pixel in the vicinity where the contact 23 is provided, the dark current increases due to the contact 23. For example, in the arrangement illustrated in FIG. 2A, the contact 23 is provided at a position surrounded by the sub-pixels 21A and 21C of the pixel 21 and the sub-pixels of the pixel adjacent to the pixel 21 on the left side. Therefore, in the arrangement illustrated in FIG. 2A, at least one contacts 23 are provided in the vicinity of the sub-pixels 21A, 21B, 21C, and 21D, causing an increase of overall dark current flowing through the unit pixels.

On the other hand, in the arrangement illustrated in FIG. 2B, in a pixel region 30 included in the solid-state imaging device, a pixel 31 is formed of a plurality of sub-pixels 31A, 31B, 31C, and 31D. The sub-pixels 31A, 31B, 31C, and 31D are separated from each other by a pixel separation layer (a region other than the pixel in FIG. 2B).

For example, the sub-pixels 31A, 31B, 31C, and 31D may be a pixel (red pixel) with the red CF, a pixel (green pixel) with the green CF, a pixel (blue pixel) with the blue CF, and a pixel (white pixel) with no CF, respectively. At the plurality of sub-pixels 31A, 31B, 31C, and 31D, the light passes through the CFs corresponding to individual colors, enters the photodiode (PD) provided inside the pixel, and is photoelectrically converted to obtain signal charges corresponding to the individual colors.

Here, the pixel separation layer that separates the unit pixels such as the sub-pixels 31A, 31B, 31C, and 31D from each other is connected to a reference potential line 35 (e.g., the ground line) by the contact 33 provided at a predetermined position. For example, in the arrangement illustrated in FIG. 2B, the contact 33 connected to the potential line 35 is provided on the upper side or the lower side of each pixel 31 (when FIG. 2B is viewed from the front). In other words, in the arrangement illustrated in FIG. 2B, the contact 33 is provided every other pixel at a position surrounded by the sub-pixels 31A and 31B of the pixel 31 and the sub-pixels of the pixel adjacent to the pixel 31 on the upper side.

In the arrangement illustrated in FIG. 2B, at least one contact 33 is provided in the vicinity of the sub-pixels 31A and 31B, and no contact 33 is provided in the vicinity of the sub-pixels 31C and 31D. Thus, the dark current does not increase at the sub-pixels 31C and 31D where no contact 33 is provided nearby, but the dark current increases at the sub-pixels 31A and 31B where at least one contact 33 is provided nearby. In the pixel column including the sub-pixels 31A and 31B, therefore, where the dark current increases, streak-like deterioration in image quality due to the dark current may be confirmed.

In view of the above circumstances, the inventors have arrived at a technique according to the present disclosure. In the technique according to the present disclosure, a contact for fixing the pixel separation layer separating the unit pixels to the reference potential is provided at predetermined pixels, and the predetermined pixels are arranged at a predetermined interval in a two-dimensional matrix of unit pixels. According to the present disclosure, it is possible to reduce the magnitude of dark current and the inter-pixel difference in the solid-state imaging device.

### 1. Configuration

### 1.1. Planar Configuration

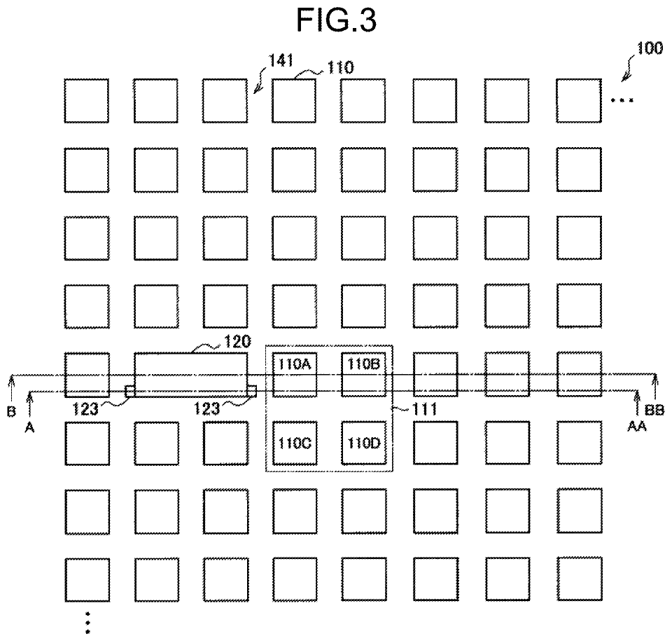

Hereinafter, a planar configuration of a solid-state imaging device according to an embodiment of the present disclosure is described with reference to FIGS. 3 to 5. FIG. 3 is a schematic explanatory diagram illustrating a planar configuration of a pixel region included in the solid-state imaging device according to the present embodiment.

As illustrated in FIG. 3, the solid-state imaging device according to this embodiment includes a pixel region 100 in which a plurality of first pixel units 110 whose regions are defined by pixel separation layers 141 are arranged in a two-dimensional matrix. In the pixel region 100, some of the first pixel units 110 are replaced by second pixel units 120.

The first pixel unit 110 includes one photoelectric conversion element and also includes one on-chip lens provided on the light incident surface on the one photoelectric conversion element. For example, the first pixel unit 110 may include, as a photoelectric conversion element, a photodiode in which a diffusion region of a second conductivity type (e.g., n-type) is formed in a first conductivity type (e.g., p-type) well (WELL). The first conductivity type well functions as a potential barrier against electrons existing in the second conductivity type diffusion region. Accordingly, the first conductivity type well functions as the pixel separation layer 141 that separates the photoelectric conversion elements included in the first pixel units 110. Each first pixel unit 110 can improve the sensitivity of the solid-state imaging device by collecting incident light with the on-chip lens and increasing the amount of light incident on the photoelectric conversion element.

The first pixel units 110 generate image signals by photoelectrically converting the incident light. The first pixel units 110 are unit pixels regularly arranged to constitute the pixel region 100, and the plurality of first pixel units 110 constitute one display unit (one pixel) of the solid-state imaging device. That is, each first pixel unit 110 functions as a sub-pixel that detects light corresponding to each color (e.g., three primary colors of light) of the pixel 111, and the plurality of first pixel units 110 constitute a pixel 111. For example, the pixel 111 may be formed of four first pixel units 110A, 110B, 110C, and 110D. At this time, the first pixel units 110A, 110B, 110C, and 110D may function as a red pixel, a green pixel, a blue pixel, and a white pixel, respectively.

The first pixel units 110 are regularly arranged in the pixel region 100 in a two-dimensional array. Specifically, the first pixel units 110 may be arranged at equal intervals in a first direction and in a second direction orthogonal to the first direction. That is, the two-dimensional arrangement of the first pixel units 110 in the pixel region 100 may be a so-called matrix arrangement in which the first pixel units 110 are arranged at positions corresponding to the vertices of a square. However, the two-dimensional arrangement of the first pixel units 110 in the pixel region 100 is not limited to the above, and may be in another arrangement.

The second pixel unit 120 includes two photoelectric conversion elements, and has one on-chip lens provided on the light incident surface across the two photoelectric conversion elements. The two photoelectric conversion elements included in the second pixel unit 120 are photodiodes which may have the same size as the photoelectric conversion element of the first pixel unit 110. In such a case, the second pixel unit 120 can be provided inside the two-dimensional array of the first pixel units 110 by replacing the two first pixel units 110.

However, the two photoelectric conversion elements included in the second pixel unit 120 may be smaller than the photoelectric conversion elements of the first pixel unit 110. That is, the planar area of one pixel included in the second pixel unit 120 may be smaller than the planar area of one pixel included in the first pixel unit 110. For example, the entire planar area of the second pixel unit 120 may be the same as the planar area of the first pixel unit 110.

The second pixel unit 120 functions as a ranging pixel using pupil division phase difference autofocus. Specifically, the second pixel unit 120 photoelectrically converts, for example, the light beam incident from the left side of the on-chip lens with the left pixel, and the light beam incident from the right side of the on-chip lens with the right pixel. At this time, the output from the left pixel of the second pixel unit 120 and the output from the right pixel of the second pixel unit 120 are shifted (which is also referred to as a shift amount) along the arrangement direction of the two pixels. Since the shift amount of the two pixel outputs is a function of the defocus amount with respect to the focal plane of the imaging surface, the second pixel unit 120 can compare the output from the two pixels to obtain the defocus amount or measure the distance to the imaging surface.

In addition, the second pixel unit 120 may include a shielding film that shields the light incident on the left and right sides of the pixel at different regions of each pixel to more clearly divide the light beam incident from the left side of the on-chip lens and the light beam incident from the right side of the on-chip lens. For example, the second pixel unit 120 may be a ranging pixel that divides the pupil by using both of the one on-chip lens and the light shielding film which are provided over two pixels.

The signal photoelectrically converted by the second pixel unit 120 is used for ranging or autofocusing. Therefore, the two pixels in the second pixel unit 120 may have any filter color. That is, the two pixels included in the second pixel unit 120 may be red, green, blue, or white pixels. However, the second pixel unit 120 may use a green pixel or a white pixel which can obtain a smaller light loss by the color filter and a larger incident light amount on the photoelectric conversion element, thus improving the accuracy of ranging or autofocusing.

Note that the magnitude of the signal output from the second pixel unit 120 may be larger than the magnitude of the signal output from the first pixel unit 110. As will be described later, the second pixel unit 120 functions as a ranging pixel, and can perform ranging more reliably by increasing the signal output from the second pixel unit 120.

In the above embodiment, the second pixel unit 120 has been described to include two photoelectric conversion elements and has one on-chip lens provided on the light incident surface across the two photoelectric conversion elements, but the technique according to the present disclosure is not limited thereto. Alternatively, for example, the second pixel unit 120 may be a ranging pixel unit capable of detecting the defocus amount using pupil division with the light shielding film, a pixel unit capable of executing both generating and ranging functions of the image signal as being configured by one unit pixel including two photoelectric conversion elements, or a pixel unit capable of receiving light in a specific wavelength band such as infra-red (IR).

Further, the second pixel unit 120 may include two or more combinations of two photoelectric conversion elements and one on-chip lens provided on the light incident surface across the two photoelectric conversion elements. According to this configuration, the second pixel unit 120 can perform ranging more accurately with respect to imaging targets having various shapes.

The second pixel unit 120 is provided by replacing the two first pixel units 110 in the two-dimensional matrix array in which the first pixel units 110 are arranged. For example, at least one second pixel unit 120 may be provided in a region where a total of eight first pixel units 110 of 2×4 are arranged. Alternatively, at least one second pixel unit 120 may be provided in a region where a total of 16 first pixel units 110 in four squares are arranged, and also at least one second pixel unit 120 may be provided in the region where a total of 64 first pixel units 110 in eight squares are arranged.

The pixel separation layer 141 forms a potential barrier against electrons generated in each of the photoelectric conversion elements included in the first pixel unit 110 and the second pixel unit 120. Thus, the pixel separation layer 141 can separate the photoelectric conversion elements from each other. Specifically, the pixel separation layer 141 is a semiconductor layer including a first conductivity type impurity (e.g., p-type) provided between the second conductivity type (e.g., n-type) diffusion regions of the photoelectric conversion element. Accordingly, the pixel separation layer 141 separates the unit pixels from each other by separating the second conductivity type diffusion regions serving as the light receiving portions in the unit pixels.

A contact 123 fixes the potential of the pixel separation layer 141 to the reference potential by connecting the pixel separation layer 141 to the reference potential line (e.g., the ground line). The contact 123 can be formed of any metal material, for example. The contact 123 may be made of, for example, a metal such as titanium (Ti), tantalum (Ta), tungsten (W), aluminum (Al), or copper (Cu), or an alloy or compound of these metals.

Specifically, the contact 123 is provided in the region where the second pixel unit 120 is provided or under the pixel separation layer 141 adjacent to this region to connect the pixel separation layer 141 to the ground line or the like. For example, the contact 123 may be provided under the pixel separation layer 141 adjacent to any vertex of the rectangular region in which the second pixel unit 120 is provided. In the configuration illustrated in FIG. 3, the contacts 123 are provided under the pixel separation layer 141 adjacent to the vertexes that sandwich the long side of the rectangular region in which the second pixel unit 120 is provided.

At least one contact 123 needs to be provided in the region where the second pixel unit 120 is provided or under the pixel separation layer 141 adjacent to this region. The upper limit number of the contacts 123 is not particularly specified, but may be about 3 to 4.

In the solid-state imaging device according to the present embodiment, the contacts 123 are provided in the vicinity of the second pixel unit 120 used for ranging. Although the dark current increases in the unit pixels around the contacts 123, the output from the second pixel unit 120 is not used as the pixel signal of the captured image to prevent the influence of forming the contacts 123 on the captured image.

In addition, as described above, the second pixel unit 120 is provided in a part of the two-dimensional matrix array in which the first pixel units 110 are arranged. Therefore, the contacts 123 are provided in the inner region or the region adjacent to the second pixel units 120 to reduce the total number of contacts 123 provided in the pixel region 100 and the total amount of dark current flowing in the entire pixel region 100.

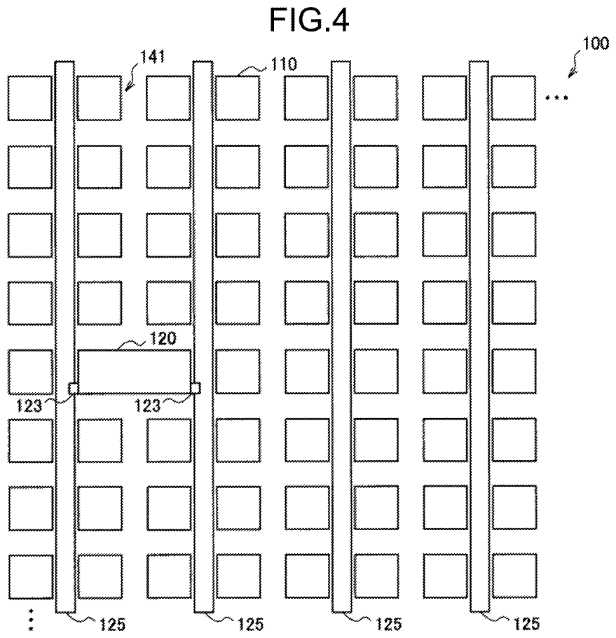

Here, with reference to FIG. 4, the arrangement of reference potential lines connected to the pixel separation layer 141 is described. FIG. 4 is a schematic plan view for explaining the arrangement of reference potential lines for unit pixels in the pixel region 100.

As illustrated in FIG. 4, ground lines 125 for providing the reference potential may extend between the first pixel units 110 that are regularly arranged. In addition, each ground lines 125 may extend in the same direction. For example, the ground lines 125 may extend on every other portion between the first pixel units 110 so as to sandwich the second pixel units 120. However, the ground lines 125 extend in accordance with the positions where the contacts 123 are provided. Therefore, the arrangement of the ground lines 125 is not limited to the configuration illustrated in FIG. 4. The extending direction and the extending interval of the ground lines 125 may appropriately be changed according to the positions of the contacts 123.

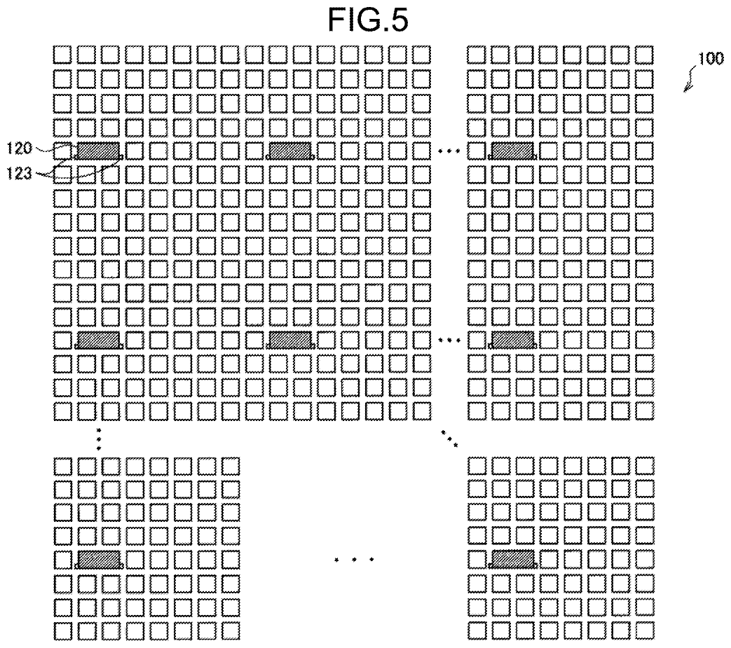

Next, the arrangement of the second pixel units 120 in a wider range of the pixel region 100 is described with reference to FIG. 5. FIG. 5 is a schematic plan view for explaining the arrangement of the second pixel units 120 in a range of the pixel region 100 wider than that of FIG. 3.

As illustrated in FIG. 5, the second pixel units 120 with surrounding contacts 123 can be arranged at predetermined intervals at least in a row in a first direction in which the first pixel units 110 are arranged. Specifically, the second pixel units 120 may be periodically arranged in a row in the first direction in which the first pixel units 110 are arranged with a predetermined number of first pixel units 110 interposed therebetween. For example, the second pixel units 120 may be periodically arranged in a row direction of the matrix in the two-dimensional matrix arrangement of the first pixel units 110.

In addition, the second pixel units 120 with surrounding contacts 123 may be further arranged at predetermined intervals at least in a row in the second direction orthogonal to the first direction. Specifically, the second pixel units 120 may be periodically arranged in a row in a second direction orthogonal to the first direction with a predetermined number of first pixel units 110 interposed therebetween. For example, the second pixel units 120 may be periodically arranged in a column direction of the matrix in the two-dimensional matrix arrangement of the first pixel units 110.

However, the arrangement of the second pixel units 120 may not be periodic throughout the pixel region 100. The arrangement of the second pixel units 120 and the contacts 123 needs to be periodic at least partly or entirely in the row extending in either the first direction or the second direction. Further, the periodicity of the arrangement of the second pixel units 120 may change for each region of the pixel region 100. For example, the periodicity of the arrangement of the second pixel units 120 including the contacts 123 may change between the central portion of the pixel region 100 and the peripheral portion of the pixel region 100.

In addition, the second pixel units 120 with the surrounding contacts 123 may be periodically arranged in a predetermined region instead of the predetermined direction such as the first direction or the second direction. For example, the second pixel units 120 including the contacts 123 may be arranged at a point-symmetrical position with a predetermined first pixel unit 110 being as the center point in the predetermined region.

Accordingly, the contacts 123 and the second pixel units 120 can be arranged at the equal density in the entire pixel region 100, so that the solid-state imaging device can obtain a uniform image in the entire pixel region 100.

Note that, to correct the influence of the dark current due to the contacts 123 in the pixel signals generated by the first pixel units 110, the light shielding region including the first pixel units 110 in which the light from the imaging target is shielded by the light shielding film needs to be formed in part of or outside the pixel region 100.

For example, the pixel region 100 may include an effective region where the light from the imaging target enters and a shielding region where the light from the imaging target is shielded by the light shielding film, and the first pixel units 110 and the second pixel units 120 may be provided in both of the effective region and the shielding region. In the light shielding region, the light from the imaging target is shielded, so that the signal based on the dark current is generated as the pixel signal from the first pixel unit 110 or the second pixel unit 120 in the light shielding region. Therefore, it is possible to generate the pixel signal from which the influence of dark current is eliminated by subtracting the corresponding signal output of the first pixel unit 110 and the second pixel unit 120 provided in the shielding region from the signal output of the first pixel unit 110 and the second pixel unit 120 provided in the effective region.

### 1.2. Cross-Sectional Configuration

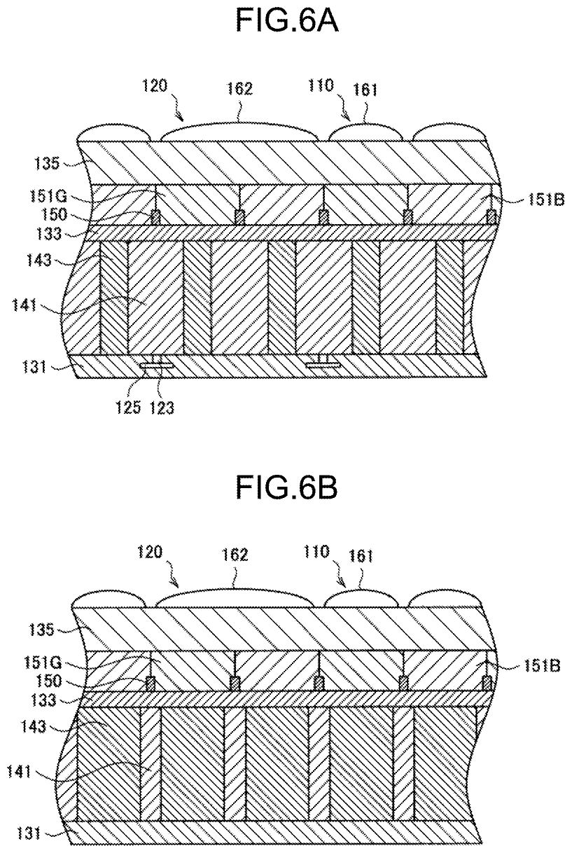

Next, a cross-sectional configuration of the solid-state imaging device according to the present embodiment is described with reference to FIGS. 6A and 6B. FIG. 6A is a schematic cross-sectional view of the pixel region illustrated in FIG. 3 cut along the plane A-AA, and FIG. 6B is a schematic cross-sectional view of the pixel region illustrated in FIG. 3 cut along the plane B-BB.

As illustrated in FIGS. 6A and 6B, the solid-state imaging device includes a first interlayer film 131, a pixel separation layer 141, a photoelectric conversion element 143, a second interlayer film 133, an inter-pixel light shielding film 150, and a blue filter 151B and a green filter 151G, a third interlayer film 135, a first on-chip lens 161, and a second on-chip lens 162.

The first interlayer film 131 is an insulating film in which various wirings are provided. For example, the first interlayer film 131 is provided with ground lines 125 connected to the reference potential and the contacts 123 connecting the ground lines 125 to the pixel separation layers 141. In addition, a semiconductor substrate (not illustrated) may be bonded under the first interlayer film 131, and various wirings may be connected to terminals of various transistors formed on the semiconductor substrate. The first interlayer film 131 may be made of an inorganic oxynitride such as silicon oxide (SiOₓ), silicon nitride (SiNₓ), or silicon oxynitride (SiON), or the like.

The ground line 125 is a wiring that provides a reference potential by being electrically connected to, for example, a housing of an electronic device in which the solid-state imaging device is provided, a ground wire, or the like. The ground line 125 may be made of, for example, a metal such as aluminum (Al) or copper (Cu), or an alloy of these metals.

The contact 123 is a via that connects the pixel separation layer 141 to the ground line 125. The pixel separation layer 141 is fixed to the reference potential by the contact 123. The contact 123 may be made of, for example, a metal such as titanium (Ti), tantalum (Ta), tungsten (W), aluminum (Al), or copper (Cu), or an alloy of these metals.

The pixel separation layer 141 and the photoelectric conversion element 143 are provided on the first interlayer film 131. The photoelectric conversion elements 143 are separated from each other by being planarly surrounded by the pixel separation layers 141. The photoelectric conversion element 143 is, for example, a photodiode having a pn junction. Electrons generated in the second conductivity type (e.g., n-type) semiconductor of the photoelectric conversion element 143 are extracted as charge signals, and positive holes generated in the first conductivity type (e.g., p-type) semiconductor of the photoelectric conversion element 143 are discharged to the ground line 125 or the like. The pixel separation layer 141 is, for example, a first conductivity type (e.g., p-type) semiconductor layer that separates the photoelectric conversion elements 143 from each other. Specifically, the pixel separation layer 141 may be the first conductivity type (e.g., p-type) semiconductor substrate, and the photoelectric conversion element 143 may be a photodiode provided on the first conductivity type (e.g., p-type) semiconductor substrate.

The second interlayer film 133 is provided on the pixel separation layer 141 and the photoelectric conversion element 143, and planarizes the surface on which the blue filter 151B and the green filter 151G are provided. The second interlayer film 133 may be made of a transparent inorganic oxynitride such as, for example, silicon oxide (SiOₓ), silicon nitride (SiNₓ), silicon oxynitride (SiON), aluminum oxide (Al₂O₃), titanium oxide (TiO₂) or the like.

The blue filter 151B and the green filter 151G are provided on the second interlayer film 133 in an arrangement corresponding to each of the photoelectric conversion elements 143. Specifically, the blue filter 151B and the green filter 151G are provided in an arrangement in which one blue filter 151B or green filter 151G is provided on one photoelectric conversion element 143. The blue filter 151B and the green filter 151G are, for example, color filters for blue pixels and green pixels, respectively, that transmit light in a wavelength band corresponding to either green or blue color. Note that the blue filter 151B and the green filter 151G may be replaced by the red filter for red pixels or transparent filter for white pixels depending on the arrangement of unit pixels. The light passes through the blue filter 151B and the green filter 151G and enters the photoelectric conversion elements 143, whereby the image signals of colors corresponding to the color filters are acquired.

The inter-pixel light shielding film 150 is provided on the second interlayer film 133 in an arrangement corresponding to the pixel separation layer 141. Specifically, the inter-pixel light-shielding film 150 is provided on the pixel separation layer 141 between the photoelectric conversion elements 143 to prevent stray light reflected inside the solid-state imaging device from entering adjacent photoelectric conversion elements 143. Such an inter-pixel light shielding film 150 is also referred to as a black matrix. The inter-pixel light-shielding film 150 can be made of a light-shielding material such as aluminum (Al), tungsten (W), chromium (Cr), or graphite.

The third interlayer film 135 is provided on the blue filter 151B and the green filter 151G, and functions as a protective film that protects the lower layer configuration such as the blue filter 151B and the green filter 151G from the external environment. The third interlayer film 135 may be made of a transparent inorganic oxynitride, for example, silicon oxide (SiOₓ), silicon nitride (SiNₓ), silicon oxynitride (SiON), aluminum oxide (Al₂O₃), titanium oxide (TiO₂) or the like.

The first on-chip lens 161 and the second on-chip lens 162 are provided on the third interlayer film 135 in an arrangement corresponding to the blue filter 151B and the green filter 151G. Specifically, the first on-chip lens 161 is arranged such that one first on-chip lens 161 is provided on one blue filter 151B or green filter 151G. That is, the first on-chip lens 161 is arranged such that one on-chip lens is provided on one unit pixel to constitute the first pixel unit 110. On the other hand, the second on-chip lens 162 is arranged such that one second on-chip lens 162 is provided on the two blue filters 151B or the green filter 151G. That is, the second on-chip lens 162 is arranged such that one on-chip lens is provided on two unit pixels to constitute the second pixel unit 120. The first on-chip lens 161 and the second on-chip lens 162 collect the light incident on the photoelectric conversion element 143 via the blue filter 151B and the green filter 151G to improve the photoelectric conversion efficiency, thus improving the sensitivity of the solid-state imaging device.

Such a solid-state imaging device can include, in the pixel region 100, the contacts 123 that fix the pixel separation layer 141, which separates the photoelectric conversion elements 143, to the reference potential are arranged at an appropriate density to reduce the total amount of the dark current. In addition, it is possible to reduce the influence of the dark current, which increases around the contacts 123, on the image quality of the captured image.

### 2. Modification

### 2.1. First modification

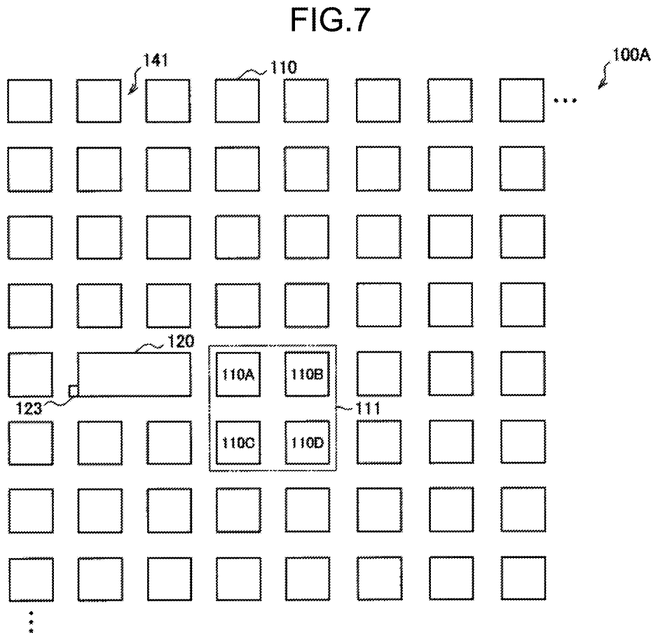

Next, a first modification of the solid-state imaging device according to the present embodiment is described with reference to FIGS. 7 to 10. The solid-state imaging device according to the first modification is a modification in which one contact is provided under the pixel separation layer 141 in a region inside or adjacent to the second pixel unit 120.

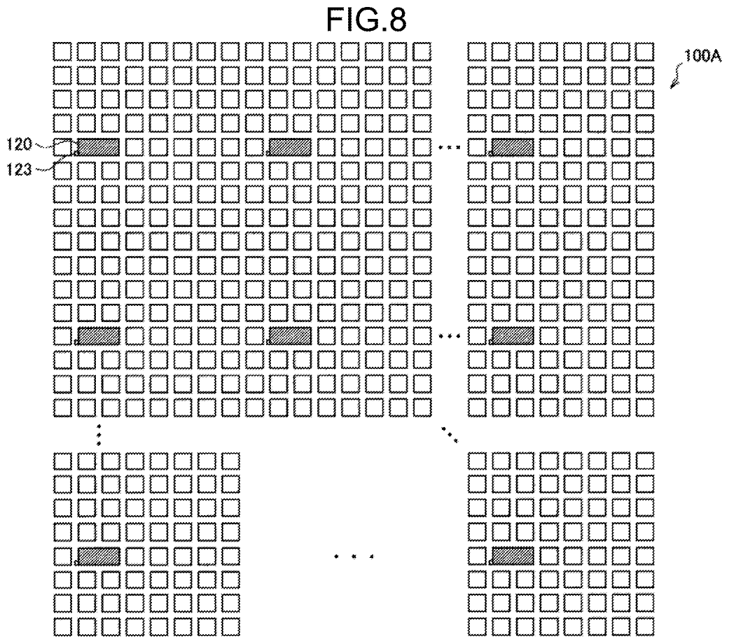

FIG. 7 is a schematic explanatory diagram illustrating an example of a planar configuration of a pixel region in the solid-state imaging device according to the first modification, and FIG. 8 is a schematic plan view illustrating the arrangement of the second pixel units 120 in a range of the pixel region 100A wider than that of FIG. 7.

As illustrated in FIG. 7, in the pixel region 100A according to the example of the first modification, a plurality of first pixel units 110 whose regions are defined by the pixel separation layers 141 are arranged in a two-dimensional matrix. For example, one pixel 111 is formed of the first pixel units 110A, 110B, 110C, and 110D functioning as sub-pixels. In addition, in the pixel region 100, some of the first pixel units 110 are replaced by second pixel units 120. The configurations of the first pixel unit 110, the second pixel unit 120, and the pixel separation layer 141 are substantially the same as the configurations described above, and the description thereof is not repeated here.

Here, in the pixel region 100A according to the example of the first modified example, one contact 123 is provided in the region where the second pixel unit 120 is provided, or under the pixel separation layer 141 adjacent to this region, to connect the pixel separation layer 141 to the ground line or the like. Specifically, the contact 123 is provided under the pixel separation layer 141 adjacent to one vertex of long side of the rectangular region in which the second pixel unit 120 is provided.

In addition, as illustrated in FIG. 8, the second pixel units 120 each having the one contact 123 provided around unit may be arranged at predetermined intervals at least in one row in the first direction in which the first pixel units 110 are arranged. For example, the second pixel units 120 may be periodically arranged in a row direction of the matrix in the two-dimensional matrix arrangement of the first pixel units 110. In addition, the second pixel units 120 may be arranged at predetermined intervals at least in a row in the second direction orthogonal to the first direction. For example, the second pixel units 120 may be periodically arranged in a column direction of the matrix in the two-dimensional matrix arrangement of the first pixel units 110.

However, the arrangement of the second pixel units 120 and the contacts 123 may not be periodic throughout the pixel region 100A. The arrangement of the second pixel units 120 and the contacts 123 needs to be periodic at least partly or entirely in the row extending in either the first direction or the second direction. Further, the periodicity of the arrangement of the second pixel units 120 may change for each region of the pixel region 100A.

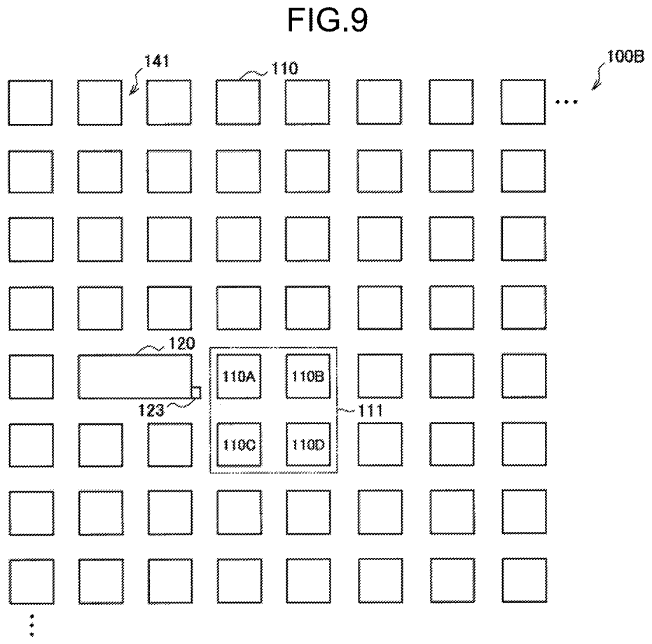

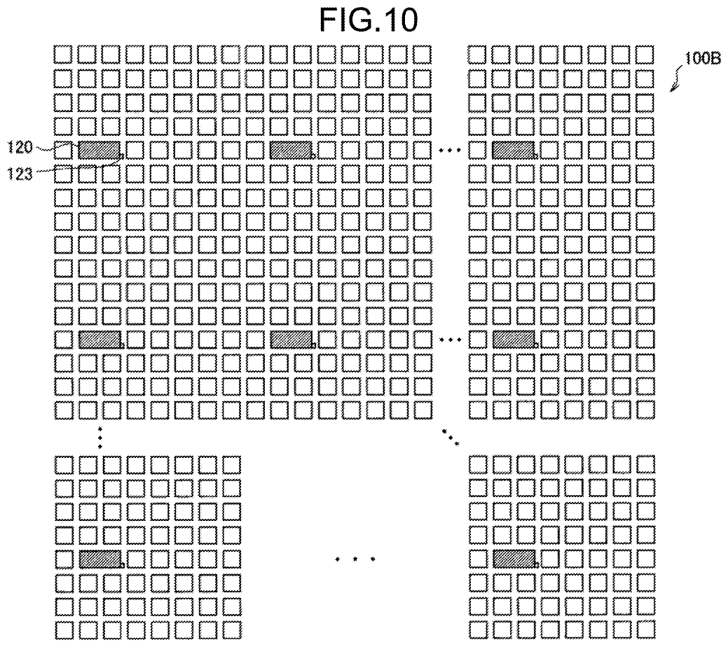

FIG. 9 is a schematic explanatory diagram illustrating another example of a planar configuration of the pixel region in the solid-state imaging device according to the first modification, and FIG. 10 is a schematic plan view illustrating the arrangement of the second pixel units 120 in a range of the pixel region 100B wider than that of FIG. 9.

As illustrated in FIG. 9, in the pixel region 100B according to another example of the first modification, the first pixel units 110 whose regions are defined by the pixel separation layers 141 are arranged in a two-dimensional matrix. For example, one pixel 111 is formed of the first pixel units 110A, 110B, 110C, and 110D functioning as sub-pixels. In addition, in the pixel region 100, some of the first pixel units 110 are replaced by second pixel units 120. The configurations of the first pixel unit 110, the second pixel unit 120, and the pixel separation layer 141 are substantially the same as the configurations described above, and the description thereof is not repeated here.

Here, in the pixel region 100B according to another example of the first modification, one contact 123 is provided in the region where the second pixel unit 120 is provided or under the pixel separation layer 141 adjacent to the region to connect the pixel separation layer 141 to the ground line or the like. Specifically, the contact 123 is provided under the pixel separation layer 141 adjacent to one vertex of long side of the rectangular region in which the second pixel unit 120 is provided.

In addition, as illustrated in FIG. 10, the second pixel units 120 each provided with the surrounding one contact 123 are arranged at predetermined intervals in at least one row in the first direction in which the first pixel units 110 are arranged. For example, the second pixel units 120 may be periodically arranged in a row direction of the matrix in the two-dimensional matrix arrangement of the first pixel units 110. In addition, the second pixel units 120 may be arranged at predetermined intervals at least in a row in the second direction orthogonal to the first direction. For example, the second pixel units 120 may be periodically arranged in a column direction of the matrix in the two-dimensional matrix arrangement of the first pixel units 110.

However, the arrangement of the second pixel unit 120 and the contact 123 may not be periodic throughout the pixel region 100B. The arrangement of the second pixel units 120 and the contacts 123 needs to be periodic at least partly or entirely in the row extending in either the first direction or the second direction. Further, the periodicity of the arrangement of the second pixel units 120 may change for each region of the pixel region 100B.

According to the solid-state imaging device according to the first modification, the contacts 123 that fix the pixel separation layer 141, which separates the photoelectric conversion elements 143, to the reference potential are arranged at an appropriate density to reduce the total amount of dark current. In addition, according to the solid-state imaging device according to the first modification, it is possible to further reduce the influence of the dark current increasing around the contact 123 on the image quality of the captured image.

### 2.2. Second Modification

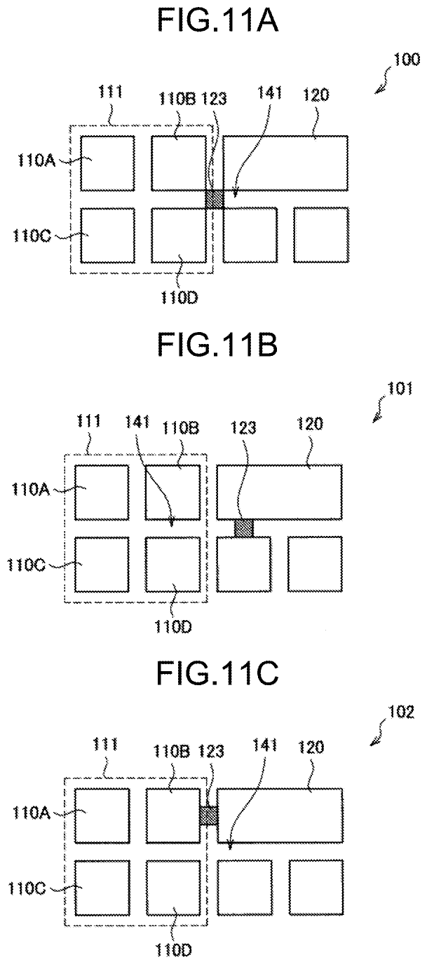

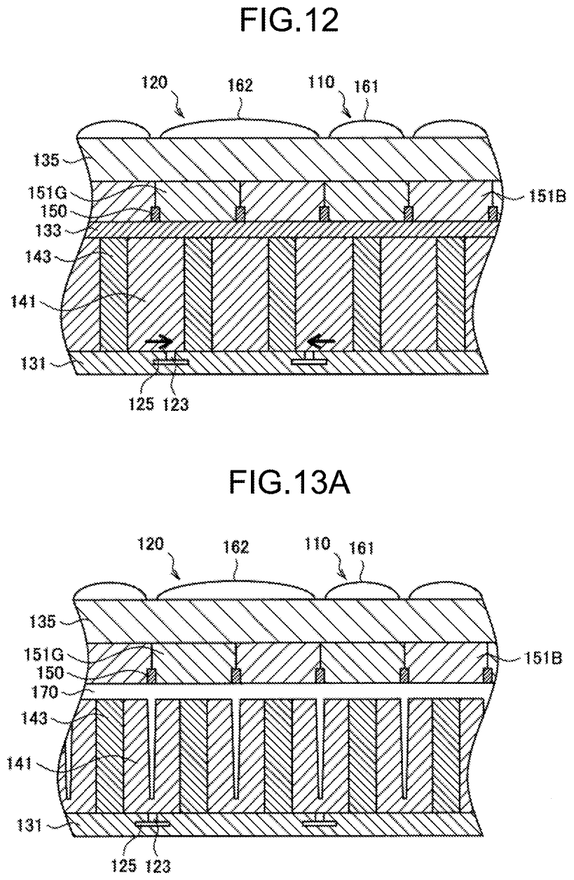

Next, a second modification of the solid-state imaging device according to the present embodiment is described with reference to FIGS. 11A to 12. The solid-state imaging device according to the second modification illustrates variations in the position of the contact 123 provided under the pixel separation layer 141 in the region inside or adjacent to the second pixel unit 120.

FIG. 11A to FIG. 11C are explanatory views illustrating the vicinity of the pixel region where the second pixel unit is provided in an enlarged manner to illustrate variations of the position where the contact is provided.

As illustrated in FIG. 11A, the contact 123 connecting the pixel separation layer 141 to the ground line or the like may be provided under the pixel separation layer 141 adjacent to one of the vertices of the rectangular region where the second pixel unit 120 is provided. The area adjacent to the vertex of the rectangular region where the second pixel unit 120 is provided is the intersection of the pixel separation layer 141 that separates the first pixel unit 110 (first pixel units 110A, 110B, 110C, 110D) and the photoelectric conversion elements of the second pixel unit 120. Accordingly, by providing the contact 123 at the intersection of the pixel separation layer 141, it is possible to increase an allowable alignment error amount with the pixel separation layer 141 when the contact 123 is formed. Therefore, the contact 123 connected to the pixel separation layer 141 can be more easily formed.

As illustrated in FIG. 11B, the contact 123 that connects the pixel separation layer 141 to the ground line or the like may be provided under the pixel separation layer 141 adjacent to the long side of the rectangular region where the second pixel unit 120 is provided. When the contact 123 is provided in the pixel separation layer 141 adjacent to the long side of the rectangular region where the second pixel unit 120 is provided, the first pixel units 110A, 110B, 110C, and 110D can be arranged further separated from the contact 123. Therefore, the increase in the dark current due to the formation of the contact 123 can be reduced in the first pixel units 110A, 110B, 110C, and 110D. Accordingly, the image signal quality of the pixel 111, which is formed of the first pixel units 110A, 110B, 110C, and 110D and is adjacent to the second pixel unit 120, can be improved.

As illustrated in FIG. 11C, the contact 123 connecting the pixel separation layer 141 to the ground line or the like may be provided under the pixel separation layer 141 adjacent to the short side of the rectangular region where the second pixel unit 120 is provided. When the contact 123 is provided in the pixel separation layer 141 adjacent to the short side of the rectangular region in which the second pixel unit 120 is provided, the first pixel units 110C and 110D can be arranged further separated from the contact 123. Therefore, the increase in the dark current due to the formation of the contact 123 can be reduced in the first pixel units 110C and 110D. Such a configuration may improve the quality of the image signal of the first pixel units 110C and 110D, if the first pixel units 110C and 110D are pixels easily affected by the dark current.

In addition, as described with reference to FIG. 12, each contact 123 may be formed at a position closer to the second pixel unit 120 in the width direction of the pixel separation layer 141. FIG. 12 is a schematic cross-sectional view illustrating a variation of the contact position in the cross-sectional structure obtained by cutting the pixel region illustrated in FIG. 3 along the plane A-AA.

As illustrated in FIG. 12, the contact 123 may be formed at a position closer to the center of the second pixel unit 120 in the width direction of the pixel separation layer 141. In such a case, the distance between the contact 123 and the surrounding first pixel unit 110 can be further apart, so that the increase in the dark current of the first pixel unit 110 due to the formation of the contact 123 can be prevented. In the structure illustrated in FIG. 12, the contact 123 is formed inside the region where the second pixel unit 120 is provided.

Here, as illustrated in FIG. 12, the photoelectric conversion element 143 may not be provided in the entire region where the blue filter 151B or the green filter 151G is provided. This is because when the photoelectric conversion element 143 is provided over the entire region where the blue filter 151B or the green filter 151G is provided, the separation of the photoelectric conversion element 143 by the pixel separation layer 141 may not function sufficiently. In addition, the light incident on the photoelectric conversion element 143 is collected by the first on-chip lens 161 or the second on-chip lens 162, the photoelectric conversion element 143 only needs to be large enough for photoelectric conversion.

### 2.3. Third Modification

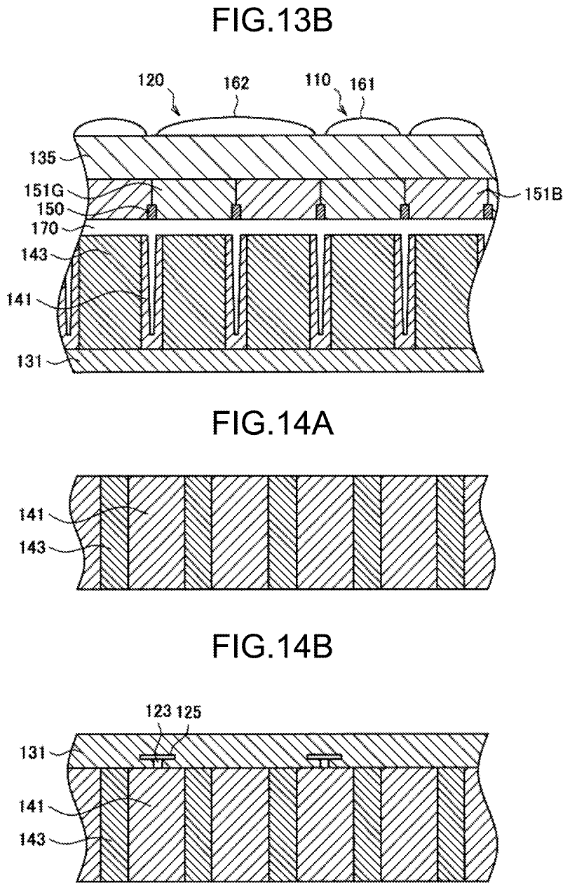

Further, a third modification of the solid-state imaging device according to the present embodiment is described with reference to FIGS. 13A and 13B. The solid-state imaging device according to the third modification is a modification in which an insulating layer is provided inside the pixel separation layer 141 to improve the electrical insulating property of each photoelectric conversion element.

FIG. 13A is a schematic cross-sectional view of the pixel region illustrated in FIG. 3 cut along the plane A-AA in the third modification, and FIG. 13B is a schematic cross-sectional view of the pixel region illustrated in FIG. 3 cut along the plane B-BB in the third modification.

As illustrated in FIGS. 13A and 13B, the solid-state imaging device includes the first interlayer film 131, the pixel separation layer 141, a pixel insulating layer 170, the photoelectric conversion element 143, the inter-pixel light-shielding film 150, and the blue filter 151B and the green filter 151G, the third interlayer film 135, the first on-chip lens 161, and the second on-chip lens 162. Since the configuration other than the pixel insulating layer 170 is substantially the same as the configuration described with reference to FIGS. 6A and 6B, the description thereof is not repeated here.

The pixel insulating layer 170 is provided on the pixel separation layer 141 and the photoelectric conversion element 143, and is provided in the depth direction from above the pixel separation layer 141 toward the inside of the solid-state imaging device. Specifically, the pixel insulating layer 170 may be formed by embedding an insulating material in an opening provided substantially vertically from the blue filter 151B and green filter 151G side of the pixel separation layer 141 toward the first interlayer film 131 side. Since the pixel insulating layer 170 is formed using an insulating material, each of the photoelectric conversion elements 143 can be more reliably separated by electrically insulating each of the photoelectric conversion elements 143 included in each pixel.

For example, the pixel insulating layer 170 may be formed by removing a predetermined region of the pixel separation layer 141 by etching or the like, and then filling the opening formed by etching with the insulating material and flattening the surface by chemical mechanical polishing (CMP) or the like. As the insulating material for forming the pixel insulating layer 170, silicon oxide (SiOₓ), silicon nitride (SiNₓ), silicon oxynitride (SiON), or the like may be used.

### 3. Manufacturing Method

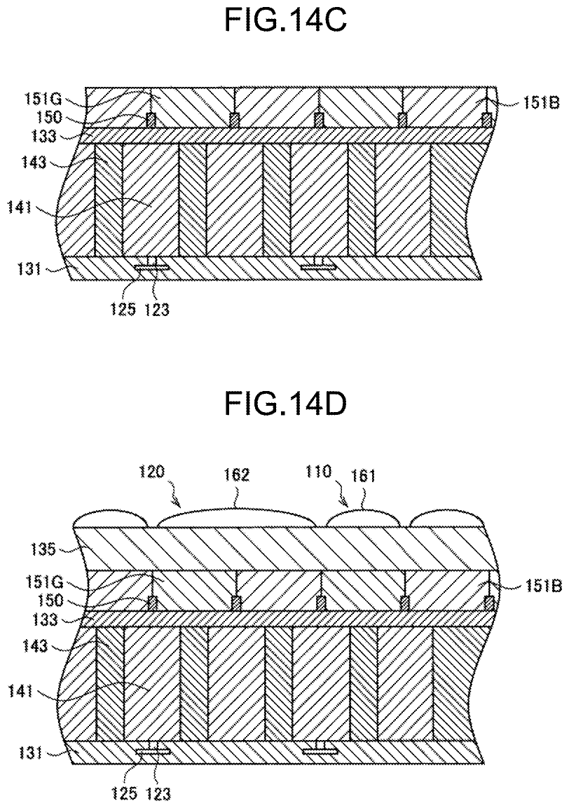

Here, a method of manufacturing the solid-state imaging device according to the present embodiment is described with reference to FIGS. 14A to 14D. FIGS. 14A to 14D are schematic cross-sectional views for explaining a manufacturing process of the method of manufacturing the solid-state imaging device according to the present embodiment.

First, as illustrated in FIG. 14A, conductive impurities are introduced into a semiconductor substrate made of silicon or the like to form the pixel separation layer 141 and the photoelectric conversion element 143. For example, the pixel separation layer 141 is formed by introducing a first conductivity type impurity (e.g., p-type impurity such as boron or aluminum) into the silicon substrate by ion implantation or the like. Subsequently, a photoelectric conversion element 143 is formed by introducing a second conductivity type impurity (e.g., an n-type impurity such as phosphorus or arsenic) into the silicon substrate by ion implantation or the like. The arrangement of the photoelectric conversion element 143 and the pixel separation layer 141 is determined by considering the arrangement of pixels.

Subsequently, as illustrated in FIG. 14B, the first interlayer film 131 including the contacts 123 and ground lines 125 is formed on one surface of the semiconductor substrate in which the pixel separation layer 141 and the photoelectric conversion element 143 are formed. Specifically, the first interlayer film 131 is formed on the semiconductor substrate in which the pixel separation layer 141 and the photoelectric conversion element 143 are formed by repeatedly forming an insulating layer by chemical vapor deposition (CVD) or the like and forming wirings by sputtering or the like. In addition, the contacts 123 connected to the pixel separation layer 141 at predetermined positions and the ground lines 125 connected to the contacts 123 are formed in the first interlayer film 131. Note that each ground line 125 is connected to the reference potential through, for example, a pad which is drawn externally. Thus, the contacts 123 and the ground lines 125 can fix the pixel separation layer 141 to the reference potential. Note that the positions where the contacts 123 are formed are as described above, and the detailed description thereof is not repeated here. In addition, the materials for forming the first interlayer film 131, the contacts 123, and the ground lines 125 are also as described above, and the detailed description thereof is not repeated here.

Next, as illustrated in FIG. 14C, the second interlayer film 133 is formed on the other surface of the semiconductor substrate on which the pixel separation layer 141 and the photoelectric conversion element 143 are formed, and the inter-pixel light shielding film 150, the blue filter 151B, and the green filter 151G are formed on the second interlayer film 133. Specifically, the second interlayer film 133 is first formed on the other surface of the semiconductor substrate facing the one surface, on which the first interlayer film 131 is formed, using CVD or the like. Thereafter, the inter-pixel light-shielding film 150 is formed on the second interlayer film 133 by sputtering or the like, and the blue filter 151B and the green filter 151G are formed. Here, the arrangement of the inter-pixel light shielding film 150, the blue filter 151B, and the green filter 151G is determined by considering the arrangement of the pixels.

Further, as illustrated in FIG. 14D, the third interlayer film 135, the first on-chip lens 161, and the second on-chip lens 162 are formed on the blue filter 151B and the green filter 151G. Specifically, the third interlayer film 135 is first formed on the blue filter 151B and the green filter 151G. Thereafter, the first on-chip lens 161 and the second on-chip lens 162 are formed on the third interlayer film 135 so as to correspond to the arrangement of the first pixel unit 110 and the second pixel unit 120, respectively. Note that the arrangement of the first on-chip lens 161 and the second on-chip lens 162 is as described above, and the detailed description thereof is not repeated here.

By the manufacturing process described above, the solid-state imaging device according to the present embodiment is manufactured. Note that specific manufacturing conditions and the like not described above can be understood by those skilled in the art and will not be described here. Note that the blue filter 151B and the green filter 151G may be a red filter for red pixels or a transparent filter for white pixels depending on the arrangement of unit pixels.

### 4. Application Examples

### 4.1 First Application Example

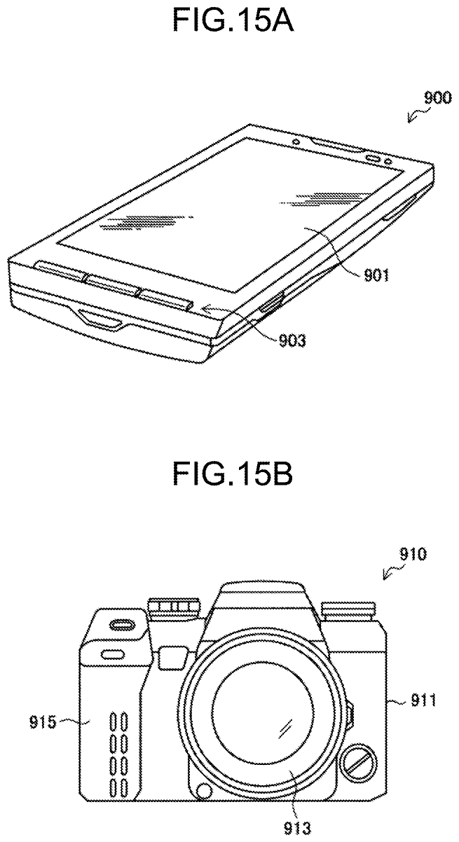

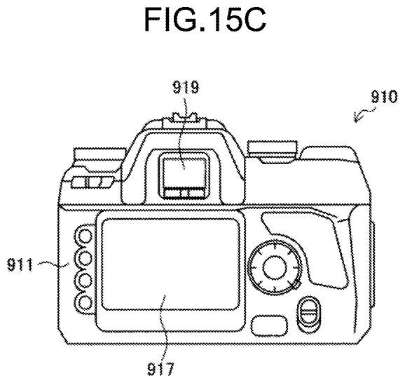

A solid-state imaging device according to an embodiment of the present disclosure can be applied to an imaging unit mounted on various electronic devices as a first application example. Next, examples of electronic devices to which the solid-state imaging device according to the present embodiment can be applied are described with reference to FIGS. 15A to 15C. FIGS. 15A to 15C are external views illustrating examples of electronic devices to which the solid-state imaging device according to this embodiment can be applied.

For example, the solid-state imaging device according to the present embodiment can be applied to an imaging unit mounted on an electronic device such as a smartphone. Specifically, as illustrated in FIG. 15A, a smartphone 900 includes a display unit 901 that displays various types of information, and an operating portion 903 including buttons and the like that receive operation inputs from the user. Here, the solid-state imaging device according to the present embodiment may be applied to the imaging unit included in the smartphone 900.

For example, the solid-state imaging device according to the present embodiment can be applied to an imaging unit mounted on an electronic device such as a digital camera. Specifically, as illustrated in FIGS. 15B and 15C, a digital camera 910 includes a main body (camera body) 911, an interchangeable lens unit 913, a grip 915 that is gripped by the user during shooting, a monitor unit 917 for displaying various types of information, and an electronic view finder (EVF) 919 for displaying a through image observed by the user at the time of shooting. Note that FIG. 15B is an external view of the digital camera 910 viewed from the front (i.e., the subject side), and FIG. 15C is an external view of the digital camera 910 viewed from the back (i.e., the photographer side). Here, the solid-state imaging device according to the present embodiment may be applied to the imaging unit of the digital camera 910.

Note that the electronic device to which the solid-state imaging device according to this embodiment is applied is not limited to the above examples. The solid-state imaging device according to the present embodiment can be applied to an imaging unit mounted on electronic devices in all fields. Examples of such electronic devices include an eyeglasses-type wearable device, a head mounted display (HMD), a television device, an electronic book, a personal digital assistants (PDA), a notebook-type personal computer, a video camera, a game device, and the like.

### 4.2. Second Application Example

Further, the technique according to the present disclosure can be applied to various other products. For example, as a second application example, the technique according to the present disclosure may be applied to the imaging device mounted on any kind of mobile body, such as an automobile, an electric vehicle, a hybrid electric vehicle, a motorcycle, a bicycle, a personal mobility, an airplane, a drone, a ship, a robot, or the like.

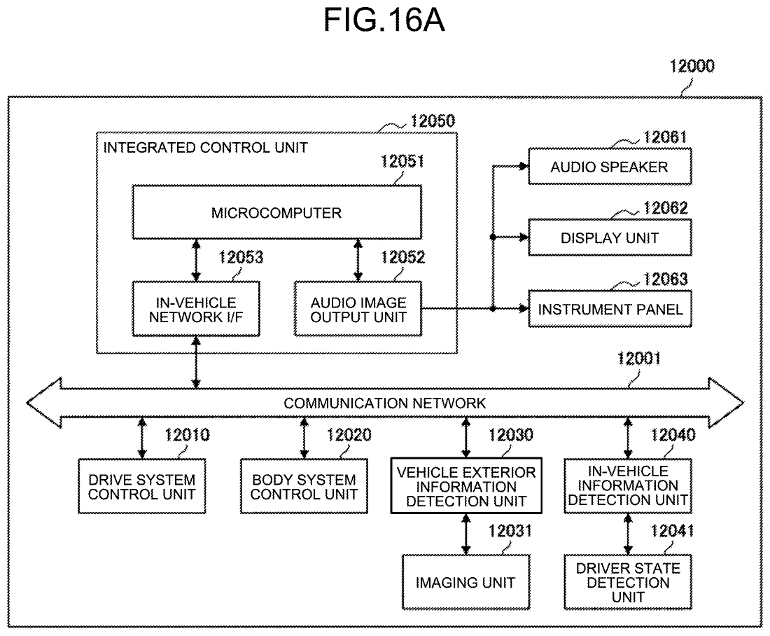

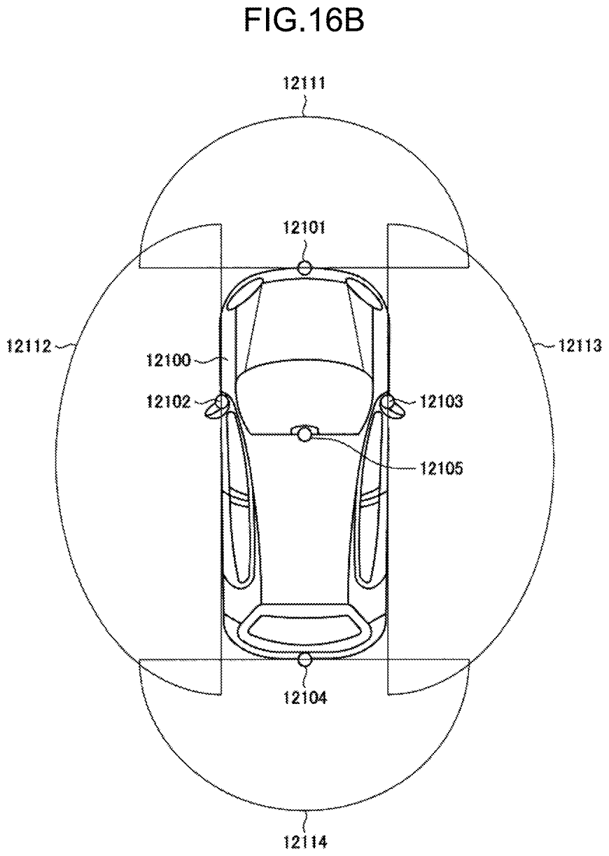

FIG. 16A is a block diagram illustrating a schematic configuration example of a vehicle control system that is an example of a mobile control system to which the technique according to the present disclosure can be applied.

A vehicle control system 12000 includes a plurality of electronic control units connected via a communication network 12001. In the example illustrated in FIG. 16A, the vehicle control system 12000 includes a drive system control unit 12010, a body system control unit 12020, a vehicle exterior information detection unit 12030, an in-vehicle information detection unit 12040, and an integrated control unit 12050. In addition, as a functional configuration of the integrated control unit 12050, a microcomputer 12051, an audio image output unit 12052, and an in-vehicle network interface (I/F) 12053 are illustrated.

The drive system control unit 12010 controls the operation of the devices related to the drive system of the vehicle according to various programs. For example, the drive system control unit 12010 functions as a driving force generation device for generating a driving force of a vehicle such as an internal combustion engine or a driving motor, a driving force transmission mechanism for transmitting the driving force to wheels, and a steering mechanism for regulating the steering angle of the vehicle, and a control device such as a braking device for generating a braking force of the vehicle.

The body system control unit 12020 controls the operation of various devices mounted on the vehicle body according to various programs. For example, the body system control unit 12020 functions as a keyless entry system, a smart key system, a power window device, or a control device for various lamps such as headlamps, rear lamps, brake lamps, blinkers, or fog lamps. In this case, the body system control unit 12020 can receive radio waves transmitted from a portable device that substitutes for a key, or signals from various switches. The body system control unit 12020 receives input of these radio waves or signals, and controls a door lock device, a power window device, lamps, and the like of the vehicle.

The vehicle exterior information detection unit 12030 detects information outside the vehicle on which the vehicle control system 12000 is mounted. For example, the imaging unit 12031 is connected to the vehicle exterior information detection unit 12030. The vehicle exterior information detection unit 12030 causes the imaging unit 12031 to capture an image outside the vehicle and receives the captured image. The vehicle exterior information detection unit 12030 may perform object detection processing of a person, a car, an obstacle, a sign, or characters on a road surface, or distance detection processing, in accordance with the received image.

The imaging unit 12031 is an optical sensor that receives light and outputs an electrical signal corresponding to the amount of received light. The imaging unit 12031 can output an electrical signal as an image or as distance measurement information. In addition, the light received by the imaging unit 12031 may be visible light or invisible light such as infrared rays.

The in-vehicle information detection unit 12040 detects vehicle interior information. For example, a driver state detection unit 12041 that detects the state of the driver is connected to the in-vehicle information detection unit 12040. The driver state detection unit 12041 includes, for example, a camera that images the driver, and the in-vehicle information detection unit 12040 may calculate, in accordance with the detected information input from the driver state detection unit 12041, the degree of tiredness or concentration of the driver or determine whether the driver is asleep.

A microcomputer 12051 is able to calculate a control target value of the driving force generation device, the steering mechanism, or the braking device, on the basis of the information inside and outside the vehicle acquired by the vehicle exterior information detection unit 12030 or the in-vehicle information detection unit 12040, to output a control command to the drive system control unit 12010. For example, the microcomputer 12051 can perform cooperative control for the purpose of implementing advanced driver assistance system (ADAS) functions including vehicle collision avoidance or impact mitigation, tracking based on inter-vehicle distance, vehicle speed maintenance, vehicle collision warning, or vehicle lane departure warning.

In addition, the microcomputer 12051 can also perform cooperative control for the purpose of automatic driving to travel the vehicle autonomously without relying on the operation control of the driver by controlling the driving force generation device, the steering mechanism, the braking device, and so on in accordance with the information around the vehicle acquired by the vehicle exterior information detection unit 12030 or the in-vehicle information detection unit 12040.

The microcomputer 12051 can output a control command to the body system control unit 12020 on the basis of the information outside the vehicle acquired by the vehicle exterior information detection unit 12030. For example, the microcomputer 12051 controls the headlamps according to the position of the preceding vehicle or oncoming vehicle detected by the vehicle exterior information detection unit 12030, and performs cooperative control for the purpose of anti-glare, such as switching a high beam to a low beam.

The audio image output unit 12052 transmits an output signal of at least one of audio and image to an output device capable of visually or audibly notifying information to a vehicle occupant or the outside of the vehicle. In the example of FIG. 16A, an audio speaker 12061, a display unit 12062, and an instrument panel 12063 are illustrated as output devices. The display unit 12062 may include at least one of an on-board display and a head-up display, for example.

FIG. 16B is a diagram illustrating an example of an installation position of the imaging unit 12031.

In FIG. 16B, the imaging unit 12031 includes imaging units 12101, 12102, 12103, 12104, and 12105.

The imaging units 12101, 12102, 12103, 12104, and 12105 are provided, for example, at positions including a front nose, a side mirror, a rear bumper, a rear door, and an upper portion of a windshield in the vehicle interior of the vehicle 12100. The imaging unit 12101 provided at the front nose and the imaging unit 12105 provided at the upper part of the windshield in the vehicle interior mainly acquire an image in front of the vehicle 12100. The imaging units 12102 and 12103 provided at the side mirrors mainly acquire images of the side of the vehicle 12100. The imaging unit 12104 provided at the rear bumper or the rear door mainly acquires an image behind the vehicle 12100. The imaging unit 12105 provided at the upper part of the windshield in the passenger compartment is mainly used for detecting a preceding vehicle or a pedestrian, an obstacle, a traffic light, a traffic sign, a lane, or the like.

Note that FIG. 16B illustrates an example of the imaging range of the imaging units 12101 to 12104. An imaging range 12111 indicates the imaging range of the imaging unit 12101 provided at the front nose, imaging ranges 12112 and 12113 indicate the imaging ranges of the imaging units 12102 and 12103 provided at the side mirrors, and an imaging range 12114 indicates the imaging range of the imaging unit 12104 provided at the rear bumper or the rear door. For example, by superimposing the image data captured by the imaging units 12101 to 12104, an overhead image when the vehicle 12100 is viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 uses the distance information obtained from the imaging units 12101 to 12104 to determine the distance to a three-dimensional object in the imaging ranges 12111 to 12114 and the temporal change of the distance (relative speed with respect to the vehicle 12100), whereby it is possible to extract, particularly as a preceding vehicle, the closest three-dimensional object on the traveling path of the vehicle 12100 and the three-dimensional object that travels at a predetermined speed (e.g., 0 km/h or more) in the same direction as the vehicle 12100. Further, the microcomputer 12051 can set an inter-vehicle distance to be secured in advance before the preceding vehicle, and can perform automatic brake control (including follow-up stop control), automatic acceleration control (including follow-up start control), and the like. Thus, it is possible to perform the cooperative control for the purpose of automatic driving or the like to travel autonomously without relying on the operation of the driver.

For example, the microcomputer 12051 can classify three-dimensional object data related to the three-dimensional object, on the basis of the distance information obtained from the imaging units 12101 to 12104, extracts the three-dimensional objects such as two-wheeled vehicles, ordinary vehicles, large vehicles, pedestrians, power poles, or the like, and uses the extracted data for automatic avoidance of obstacles. For example, the microcomputer 12051 distinguishes obstacles around the vehicle 12100 between obstacles visible to the driver of the vehicle 12100 and obstacles difficult to recognize visually. The microcomputer 12051 determines the collision risk indicating the risk of collision with each obstacle and, if the collision risk is equal to or exceeds a setting value and indicates the possibility of collision, the microcomputer 12051 can assist driving to avoid collision by outputting an alarm to the driver via the audio speaker 12061 or the display unit 12062, or executing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether a pedestrian is present in the captured images of the imaging units 12101 to 12104. Such pedestrian recognition is carried out, for example, by determining whether a person is a pedestrian by performing a pattern matching process on a sequence of feature points indicating a contour of the object and a procedure for extracting feature points in the captured images of the imaging units 12101 to 12104 as infrared cameras. When the microcomputer 12051 determines that a pedestrian exists in the captured images of the imaging units 12101 to 12104 and recognizes the pedestrian, the audio image output unit 12052 controls the display unit 12062 to display a rectangular contour line for emphasizing the recognized pedestrian. Further, the audio image output unit 12052 may control the display unit 12062 so as to display an icon or the like indicating a pedestrian at a desired position.

Heretofore, an example of a vehicle control system to which the technique according to the present disclosure can be applied has been described. The technique according to the present disclosure is applicable to the imaging unit 12031 and the like among the configurations described above. For example, the solid-state imaging device according to this embodiment can be applied to the imaging unit 12031. According to the solid-state imaging device according to the present embodiment, a higher quality image can be obtained, so that it is possible to navigate the vehicle more stably.

The preferred embodiments of the present disclosure have been described in detail above with reference to the accompanying drawings, but the technical scope of the present disclosure is not limited to such examples. It is obvious that a person having ordinary knowledge in the technical field of the present disclosure can come up with various changes or modifications within the scope of the technical idea described in the claims, and these are understood, of course, to belong to the technical scope of the present disclosure.

Further, the effects described in the present specification are merely illustrative or exemplary and are not limited. That is, the technique according to the present disclosure can exhibit other effects that are apparent to those skilled in the art from the description of the present specification in addition to or instead of the above effects.

Note that the following configurations also belong to the technical scope of the present disclosure.

(1)

A solid-state imaging device, comprising:

a plurality of first pixel units arranged in a matrix, each first pixel unit having one pixel and one on-chip lens provided on the one pixel;

at least one second pixel unit having two pixels and one on-chip lens provided across the two pixels and arranged within a matrix of the first pixel units;

a pixel separation layer that separates a photoelectric conversion layer included in each pixel of the first pixel unit from a photoelectric conversion layer included in the second pixel unit; and

at least one contact that exists within a region of the second pixel unit or is provided under the pixel separation layer adjacent to the region of the second pixel unit, and connects the pixel separation layer to a reference potential wiring, wherein

the second pixel units are arranged at predetermined intervals at least in a row extending in a first direction of the matrix of the first pixel units.

(2)

The solid-state imaging device according to (1), wherein the second pixel units are further arranged at predetermined intervals at least in a row extending in a second direction orthogonal to the first direction of the matrix of the first pixel units.

(3)

The solid-state imaging device according to (1) or (2), wherein at least one of the second pixel unit is provided in a region where the first pixel units are arranged in a 2×4 matrix.

(4)

The solid-state imaging device according to any one of (1) to (3), wherein the contact is provided adjacent to any vertex of a rectangular region in which the second pixel unit is provided.

(5)

The solid-state imaging device according to any one of (1) to (3), wherein the contact is provided adjacent to any side of a rectangular region in which the second pixel unit is provided.

(6)

The solid-state imaging device according to any one of (1) to (3), wherein the contact is provided in a region where the second pixel unit is provided.

(7)

The solid-state imaging device according to any one of (1) to (6), wherein an insulating layer formed in a thickness direction of the pixel separation layer is further provided inside the pixel separation layer.

(8)

The solid-state imaging device according to any one of (1) to (7), wherein the second pixel unit has two or more combinations of the two pixels and the one on-chip lens provided across the two pixels.

(9)

The solid-state imaging device according to any one of (1) to (8), wherein a signal output from the second pixel unit is larger than a signal output from the first pixel unit.

(10)

The solid-state imaging device according to any one of (1) to (9), wherein a planar area of one pixel included in the second pixel unit is smaller than a planar area of one pixel included in the first pixel unit.

(11)

The solid-state imaging device according to any one of (1) to (10), wherein the second pixel unit is a ranging pixel.

(12)

The solid-state imaging device according to (11), wherein the second pixel unit further includes a light shielding film that shields light incident on the two pixels at different regions of the two pixels.

(13)

The solid-state imaging device according to (11), wherein the second pixel unit includes a green pixel.

(14)

The solid-state imaging device according to any one of (1) to (13), wherein the first pixel units each include a red pixel, a green pixel, a blue pixel, or a white pixel.

(15)

The solid-state imaging device according to any one of (1) to (14), wherein

the first pixel units and the second pixel unit each include an effective region where light from an imaging target enters and a shielding region where the light from the imaging target is shielded in the pixel region,

a signal output of the first pixel units or the second pixel unit provided in the effective region is corrected by subtracting the corresponding signal output of the first pixel units or the second pixel unit provided in the shielding region.

(16)

An electronic device including a solid-state imaging device that electronically captures an imaging target, the solid-state imaging device including

a plurality of first pixel units arranged in a matrix, each first pixel unit having one pixel and one on-chip lens provided on the one pixel,

at least one second pixel unit having two pixels and one on-chip lens provided across the two pixels and arranged within a matrix of the first pixel units,

a pixel separation layer that separates a photoelectric conversion layer included in each pixel of the first pixel unit from a photoelectric conversion layer included in the second pixel unit, and

at least one contact that exists within a region of the second pixel unit or is provided under the pixel separation layer adjacent to the region of the second pixel unit, and connects the pixel separation layer to a reference potential wiring, wherein

the second pixel units are arranged at predetermined intervals at least in a row extending in a first direction of the matrix of the first pixel units.

### REFERENCE SIGNS LIST

1 SOLID-STATE IMAGING DEVICE
2 SIGNAL PROCESSING CIRCUIT
3 MEMORY
10 PIXEL REGION
11 COLUMN REGION
12 OUTPUT AMPLIFIER
100 PIXEL REGION
110 FIRST PIXEL UNIT
111 PIXEL
120 SECOND PIXEL UNIT
123 CONTACT
125 GROUND WIRE
131 FIRST INTERLAYER FILM
133 SECOND INTERLAYER FILM
135 THIRD INTERLAYER FILM
141 PIXEL SEPARATION LAYER
143 PHOTOELECTRIC CONVERSION ELEMENT
150 INTER-PIXEL LIGHT SHIELDING FILM
151B BLUE FILTER
151G GREEN FILTER
161 FIRST ON-CHIP LENS
162 SECOND ON-CHIP LENS
170 PIXEL INSULATING LAYER

What is claimed is:

1. A solid-state imaging device, comprising:
a plurality of first pixel units arranged in a matrix, each first pixel unit having one pixel and one on-chip lens provided on the one pixel;
at least one second pixel unit having two pixels and one on-chip lens provided across the two pixels and arranged within a matrix of the first pixel units;
a pixel separation layer that separates a photoelectric conversion layer included in each pixel of the first pixel unit from a photoelectric conversion layer included in the second pixel unit; and
at least one contact that exists within a region of the second pixel unit or is provided under the pixel separation layer adjacent to the region of the second pixel unit, and connects the pixel separation layer to a reference potential wiring, wherein
the second pixel units are arranged at predetermined intervals at least in a row extending in a first direction of the matrix of the first pixel units.

2. The solid-state imaging device according to claim 1, wherein the second pixel units are further arranged at predetermined intervals at least in a row extending in a second direction orthogonal to the first direction of the matrix of the first pixel units.

3. The solid-state imaging device according to claim 1, wherein at least one of the second pixel unit is provided in a region where the first pixel units are arranged in a 2×4 matrix.

4. The solid-state imaging device according to claim 1, wherein the contact is provided adjacent to any vertex of a rectangular region in which the second pixel unit is provided.

5. The solid-state imaging device according to claim 1, wherein the contact is provided adjacent to any side of a rectangular region in which the second pixel unit is provided.

6. The solid-state imaging device according to claim 1, wherein the contact is provided in a region where the second pixel unit is provided.

7. The solid-state imaging device according to claim 1, wherein an insulating layer formed in a thickness direction of the pixel separation layer is further provided inside the pixel separation layer.

8. The solid-state imaging device according to claim 1, wherein the second pixel unit has two or more combinations of the two pixels and the one on-chip lens provided across the two pixels.

9. The solid-state imaging device according to claim 1, wherein a signal output from the second pixel unit is larger than a signal output from the first pixel unit.

10. The solid-state imaging device according to claim 1, wherein a planar area of one pixel included in the second pixel unit is smaller than a planar area of one pixel included in the first pixel unit.

11. The solid-state imaging device according to claim 1, wherein the second pixel unit is a ranging pixel.

12. The solid-state imaging device according to claim 11, wherein the second pixel unit further includes a light shielding film that shields light incident on the two pixels at different regions of the two pixels.

13. The solid-state imaging device according to claim 11, wherein the second pixel unit includes a green pixel.

14. The solid-state imaging device according to claim 1, wherein the first pixel units each include a red pixel, a green pixel, a blue pixel, or a white pixel.

15. The solid-state imaging device according to claim 1, wherein
the first pixel units and the second pixel unit each include an effective region where light from an imaging target enters and a shielding region where the light from the imaging target is shielded in the pixel region,
a signal output of the first pixel units or the second pixel unit provided in the effective region is corrected by subtracting the corresponding signal output of the first pixel units or the second pixel unit provided in the shielding region.

16. An electronic device including a solid-state imaging device that electronically captures an imaging target, the solid-state imaging device including
a plurality of first pixel units arranged in a matrix, each first pixel unit having one pixel and one on-chip lens provided on the one pixel,
at least one second pixel unit having two pixels and one on-chip lens provided across the two pixels and arranged within a matrix of the first pixel units,
a pixel separation layer that separates a photoelectric conversion layer included in each pixel of the first pixel unit from a photoelectric conversion layer included in the second pixel unit, and
at least one contact that exists within a region of the second pixel unit or is provided under the pixel separation layer adjacent to the region of the second pixel unit, and connects the pixel separation layer to a reference potential wiring, wherein
the second pixel units are arranged at predetermined intervals at least in a row extending in a first direction of the matrix of the first pixel units.
